(19) United States
(12) Patent Application Publication
(10) Pub. No.: US 2025/0159966 A1
(43) Pub. Date: May 15, 2025

(54) Semiconductor Device and Method of Fabricating Thereof

(71) Applicant: Taiwan Semiconductor Manufacturing Company, Ltd., Hsinchu (TW)

(72) Inventors: Szu-Hua CHEN, Tainan City (TW); Lilin CHANG, Taipei City (TW); Yahru CHENG, Taipei (TW); Wei-Yen WOON, Taoyuan City (TW); Szuya LIAO, Hsinchu (TW)

(21) Appl. No.: 18/505,631

(22) Filed: Nov. 9, 2023

(51) Int. Cl. H01L 21/8238; H01L 21/768; H01L 27/092; H01L 29/06; H01L 29/423; H01L 29/66; H01L 29/775; H01L 29/786

(52) U.S. Cl. CPC H10D 84/038; H01L 21/76831; H10D 30/014; H10D 30/6735; H10D 62/121; H10D 64/017; H10D 84/0167; H10D 84/017; H10D 84/85; H10D 30/43; H10D 30/6757

(57) ABSTRACT

Methods for forming a stacked transistor device including depositing a dummy material such as by spin-on deposition to process a first transistor differently than a second transistor of the stacked transistor device. Multi-Vt patterning, where different transistors in a stacked device can have different threshold voltages (Vt) can be implemented by depositing a dummy material before patterning to selectively control the Vt of each transistor without affecting the others. In top-bottom FET stacks, by depositing a dummy material, the process can be optimized to ensure that each transistor in the stack is formed with the desired characteristics.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with other IC manufacturing processes. As GAA devices continue to scale, challenges have arisen when fabricating a gate structure for a GAA device, which challenges have been observed to degrade GAA device performance and increase GAA processing complexity. Accordingly, although existing GAA devices and methods for fabricating such have been generally adequate for their intended purposes, they have not been entirely satisfactory in all respects.

As the semiconductor industry further progresses into smaller technology process nodes in pursuit of higher device density, higher performance, and/or lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow diagram of an embodiment of a method of forming a dielectric material, according to one or more aspects of the present disclosure.

FIG. 2 illustrates a flow diagram of an implementation of the method of FIG. 1, according to one or more aspects of the present disclosure.

FIG. 3 illustrates a fragmentary top view of the device 300, according to one or more aspects of the present disclosure.

FIGS. 4-15 each illustrate a fragmentary cross-sectional view of the device 300, according to one or more aspects of the present disclosure.

FIG. 16 illustrates a flow diagram of an implementation of the method of FIG. 1, according to one or more aspects of the present disclosure.

FIGS. 17-24 each illustrate a fragmentary cross-sectional view of a device 2300, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is illustrative of forming a configuration of a GAA device including vertically stacked transistors. When the top multi-gate device and the bottom multi-gate device are of different conductivity types, the stacked multi-gate device may be a complementary field effect transistor (C-FET). The present disclosure provides methods of fabricating semiconductor devices such as C-FETs. However, the disclosure is not so limited. A person of skill in the art would recognize aspects of the present disclosure also apply to the formation of dielectric materials in other device types.

In the semiconductor industry, the development of high-performance transistors has been a key driver of technological progress. One way to improve transistor performance is to stack multiple transistors on top of each other, forming a 3D structure that allows for more efficient use of space and improved power efficiency. However, stacking transistors can also introduce challenges in terms of process control and device performance. To address these challenges, methods for forming a stacked transistor device including depositing a dummy material such as by spin-on deposition have been developed.

One application of these methods is in multi-Vt patterning, where different transistors in a stacked device can have different threshold voltages (Vt). By depositing a dummy material before patterning, the process can be tailored to selectively control the Vt of each transistor without affecting the others. This can allow for greater flexibility in designing stacked devices with optimized performance characteristics.

Another application is in top-bottom FET stacks, where different types of transistors are stacked vertically to achieve specific performance goals. By depositing a dummy material, the process can be optimized to ensure that each transistor in the stack is formed with the desired characteristics. This can improve overall device performance and reliability.

Thus, methods for forming a stacked transistor device including depositing a dummy material have numerous applications in the semiconductor industry. From multi-Vt patterning to top-bottom FET stacks, these methods can help improve transistor performance and reliability in a variety of applications. Such examples are provided in the following discussion.

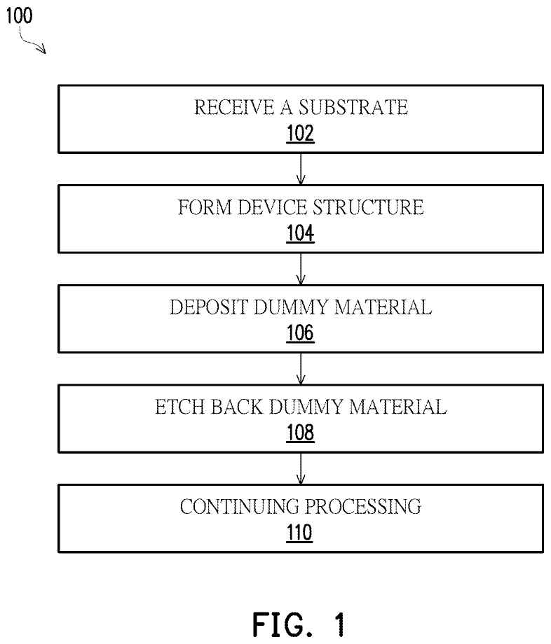

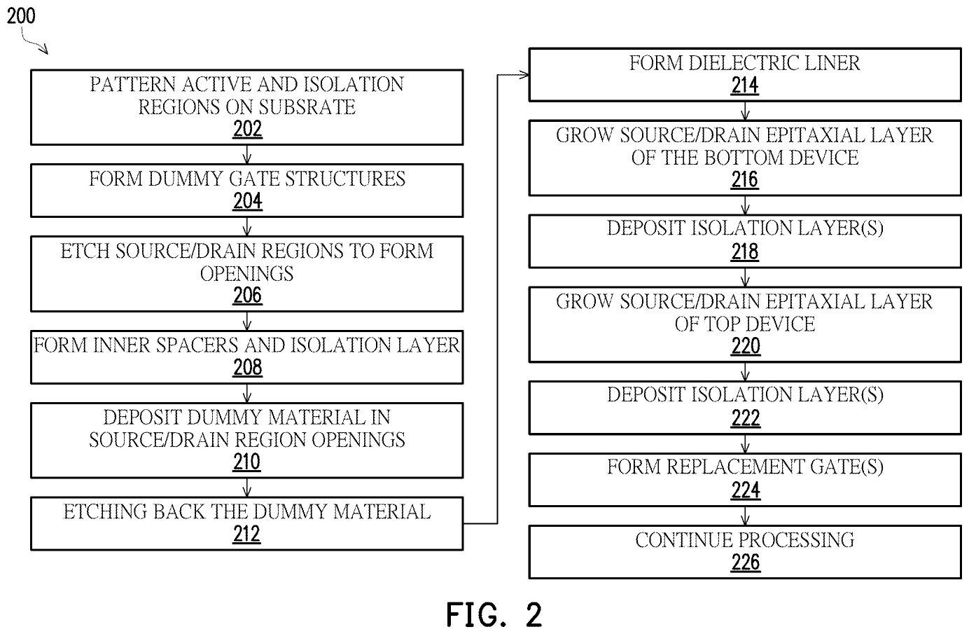

FIG. 1 is a flowchart illustrating a method 100 for forming a semiconductor structure such as a C-FET. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 may be applied in processes depicted in an embodiment illustrated in FIGS. 2-15, which are a flow chart detailing an implementation of the method 100 and corresponding fragmentary top view and cross-sectional views of a device 300 fabricated according to aspects of the method of FIG. 2.

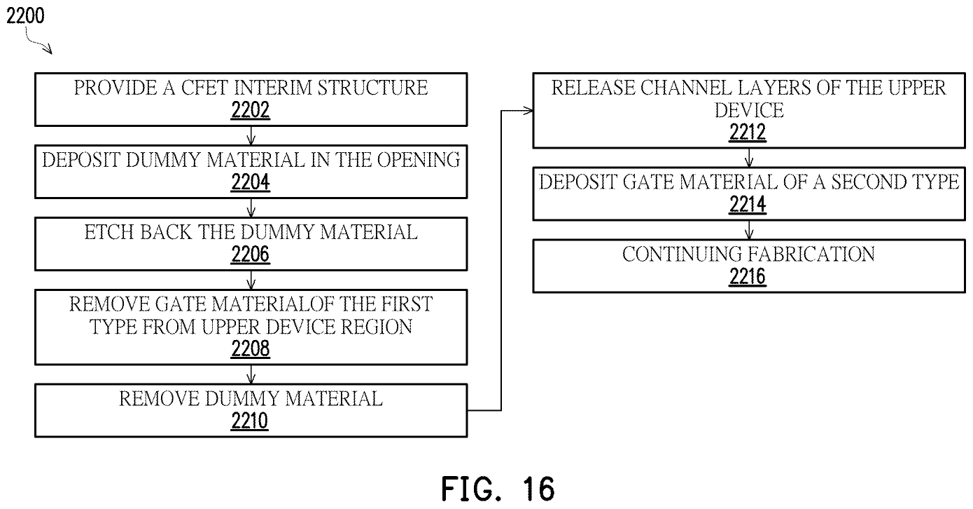

In an embodiment, the method 100 may also be applied in processes depicted in an embodiment illustrated in FIGS. 16-24, which are a flow chart detailing an embodiment of an implementation of the method 100 and corresponding fragmentary cross-sectional views of a device 2300. The features and steps of the embodiment of FIGS. 2-15 and the embodiment of FIGS. 16-24 may be used in conjunction with one another. In other words, a single device may be fabricated applying both the method 200 of FIG. 2 and method 2200 of FIG. 16. To that affect, it is noted that while the device 300 and the device 2300 include some different reference numerals, they may be the same workpiece or different regions of the same workpiece. Additionally, throughout the present application, like reference numerals denote like features, unless otherwise excepted.

Turning to FIG. 1, method 100 includes block 102, where a substrate is received. The substrate may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), gallium indium phosphide (GaInAsP), and/or other suitable materials. The substrate may be a single-layer material having a uniform composition. Alternatively, the substrate may include multiple material layers having similar or different compositions suitable for IC device manufacturing. In one example, the substrate may be a silicon-on-insulator (SOI) substrate having a silicon layer formed on a buried silicon oxide (BOX) layer. In some embodiments, the substrate includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques.

The method 100 further includes a block 104 where a device structure is formed. In some implementations, the device structure is an interim structure used to form a C-FET device. The interim structure may include an active region with one or more features of a transistor formed or partially formed. Some features that have already been formed in whole or in part on the substrate may include, for example, active regions, dielectric isolation features, gate structures, source/drain regions, contact structures, and/or other features.

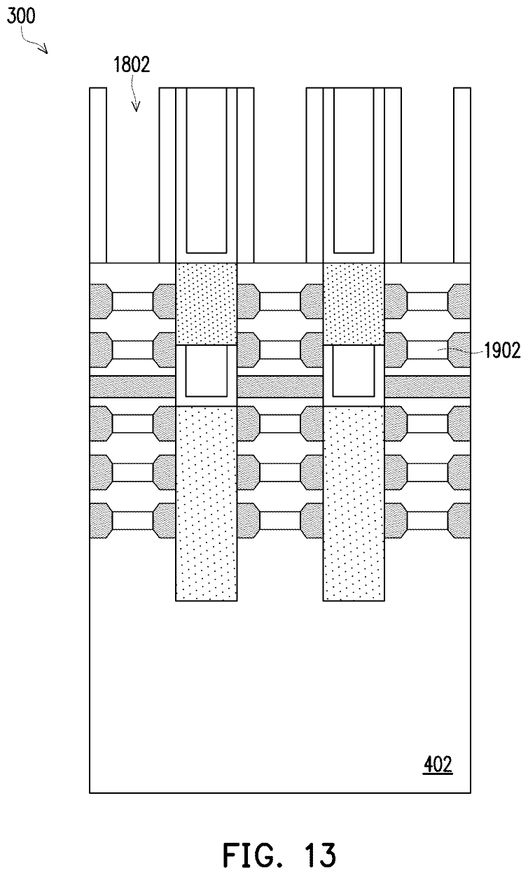

In an embodiment, the device structure includes an opening. In an implementation, the opening may be defined in a channel region of the device, such as an opening provided by removal of a dummy gate in a replacement gate process (see, e.g., FIG. 13 and the accompanying embodiments). In an implementation, the opening may be defined in a source/drain region such as provided by the recessing of source/drain regions of an active area in preparation of forming a region for growth of an epitaxial source/drain material (see, e.g., FIG. 2 and the accompanying embodiments). In other embodiment, the opening may be formed at other regions of the device structure such as a contact layer or interconnect layer. In an embodiment, the opening may have an aspect ratio of a depth greater than a width. That is, the opening may have an aspect ratio (depth:width) that is greater than 1:1. In a further embodiment, the opening filled with a dummy material may have an aspect ratio greater than 4.

At block 106 of the method 100, a dummy material is deposited on the device structure and within the opening. A dummy material is deposited forming a dummy material layer. The dummy material layer is a sacrificial layer, which is later removed from the substrate. In some implementations, the dummy material layer is used to mask certain regions of a device (e.g., a lower transistor region of a C-FET) while processing is performed another region of the device (e.g., an upper transistor region of the C-FET).

In an embodiment, the dummy material layer includes a carbon-based dielectric. In an embodiment, the dummy material layer includes a dielectric material including silicon (Si), oxygen (O), and carbon (C) such as SiOC. In an embodiment, the dummy material layer is a SiOx based dielectric.

In some implementations, a dummy material layer is formed by depositing one or more materials of Table 1, below. In a further embodiment, these precursors (e.g., Table 1) after deposition form a carbon-based. SiOC-based or SiOx based material.

Exemplary materials used to form the dummy material layer are included in the following in Table 1:

| Compound | | |
|---|---|---|
| 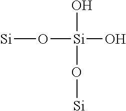 | | |
| 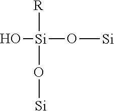 | where R is —CH₃, —C₂H₅, or other alkyl series for example with a carbon number between 1 and 10, or R is OH as above | |
| 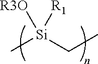 | where R1 and R3 are each one of —CH₃, —C₂H₅, or other alkyl series for example with a carbon number between 1 and 10 | where n is between approximately 10 and approximately 20 |
| 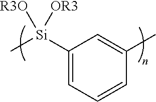 | where each R3 is one of —CH₃, —C₂H₅, or other alkyl series for example with a carbon number between 1 and 10 | where n is between approximately 10 and approximately 20 |
| 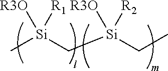 | where each R3 (R1, R2) is one of —CH₃, —C₂H₅, or other alkyl series for example with a carbon number between 1 and 10 | where the ratio of “1” to “m” is between approximately 0.5 to approximately 0.95 |

or combinations thereof. In some implementations, two, three, four or more of the materials in Table 1 may be provided together to form a dummy material deposited in block 106. The materials of Table 1 may be prepared for deposition by spin-on deposition.

In an embodiment, the deposition of the dummy material to form the dummy material layer may be performed by a spin-on deposition process, also referred to as a spin coating. In an embodiment, the spin-on deposition process is performed at a deposition temperature of between approximately 120° C. and approximately 250° C. Thus, using spin-on deposition allows for a relatively low impact to the thermal budget.

Following spin-on deposition, a hard baking step may be performed at a temperature of between approximately 250° C. and approximately 350° C. The functional groups of the composition (e.g., Si—OR) including those illustrated in the Table above, will form Si—OH ground, and two Si—OH groups can then form Si—O—Si bonding. As illustrated in the compositions in Table 1. Si—C bonding is provided by the reactant polymer of Table 1.

The spin-on deposition may be performed at a velocity between approximately 1000 and 8000 revolutions per minute (rpm). The spin-on deposition may be performed for approximately 30 seconds to approximately 60 seconds. In some implementations, a soft bake process is performed after spin-on coating. The soft bake may be a low temperature bake at for example approximately 100° C. or less. Other drying processes may also be implemented.

In an embodiment, the spin-on coating deposition allows for filling an opening with a dummy material forming a dummy material layer of a uniform consistency. In other words, the dummy material layer is formed without a seam or void. The uniformity provides several advantages including providing for uniform etch rates in subsequent processing.

The method 100 includes a block 108 where the dummy material layer is etched back. In other words, the dummy material layer is reduced in thickness. In some implementations, the dummy material layer is etched back by a chemical mechanical planarization (CMP) process, a wet etch process, a dry etch process, combinations thereof, and/or other suitable removal processes. In an embodiment, multiple etch back processes are performed. For example, a CMP process may be followed by an etching process. The etching process can include dry etching, wet etching, reactive ion etching (RIE), various plasma etches, and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. A wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant.

As discussed above, block 106 may form the dummy material layer to be substantially uniform providing the dummy material layer free of voids or seams. Thus, the etching back process may also be substantially uniform as a constant etch rate is provided throughout the material of the dummy material layer.

The method 100 then continues to a block 110 where fabrication processes are continued. In some implementations, after further processing, the dummy material may be removed from the substrate. In an embodiment, the method 100 may continue with additional deposition (block 106) and etch back (block 108) of dummy material layers. In some implementations, the method 100 continues to complete fabrication of a C-FET device, providing a stack of transistors, for example a first transistor type (e.g., p-type) as a bottom transistor and a second transistor type (e.g., n-type) as a top transistor. Various interconnects may be formed to interconnect a plurality of transistors.

The method 100 is now described with respect to various embodiments in forming a semiconductor device such as implementing the method 100 during the formation of a C-FET device. In a first exemplary embodiment, a method 200 of FIG. 2 provides an implementation of the method 100. In particular, as discussed below, in an exemplary device in block 104, a C-FET device (in interim fabrication) having a source/drain recess or opening is provided within which a dummy material layer is formed in block 106.

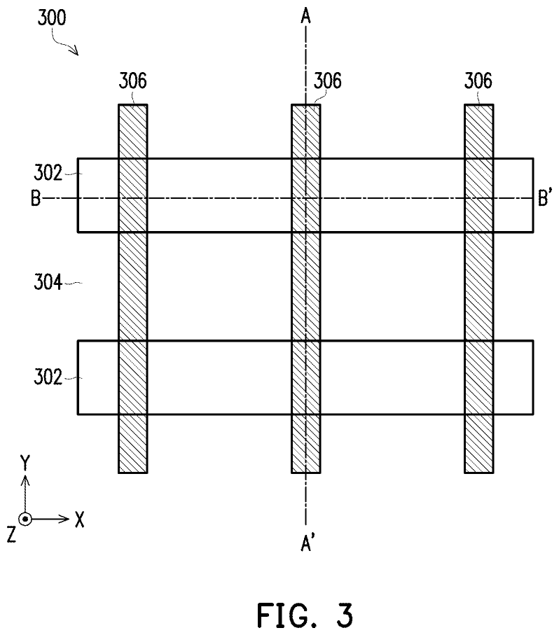

FIG. 2 is a flow chart of a method 200 for fabricating a C-FET device, according to aspects of the present disclosure. FIGS. 3-15 illustrate views of a device 300 providing exemplary illustrations of steps of the method 200. FIGS. 3-15 are simplified for ease of description and understanding. Additional steps can be provided before, during, and after the method 200, and some of the steps can be provided before, during, and after the method 200. Additional features can be added to the C-FET device 300 of FIGS. 3-15, and some of the features below can be replaced, modified, or eliminated in other embodiments.

The method 200 includes block 202 were active regions and isolation features are formed. The active regions and isolation regions may be formed on a substrate, substantially similar to the substrate discussed above with reference to the block 102 of the method 100.

Turning first to FIG. 3, a top view illustrates a plurality of active regions 302 extending in a x-direction. Isolation regions 304 interpose the active regions 302. A plurality of gate structures 306 or gate lines extend in an y-direction, perpendicular to the active regions 302. Along the x-direction, channel regions are provided under the gate structures 306 in the active regions 302 and source/drain regions are in the active regions 302 between the gate structures 306. The active regions 302, isolation regions 304, and gate structures 306 are formed on a substrate, substantially similar to the substrate discussed above with reference to block 102.

In an embodiment, the active regions 302 include a vertical stack of nanostructures (or channel members) stacked along the z-direction. In some implementations, the active regions 302 may be referred to as fins as they extend above the substrate. In an embodiment, the device 300 is configured as a C-FET, and each of the gate structures 306 includes a bottom segment and a top segment over the bottom segment. The top segment and the bottom segment may include different work function layer arrangement or different dipole components to form a bottom transistor of a first type and a top transistor of a second type.

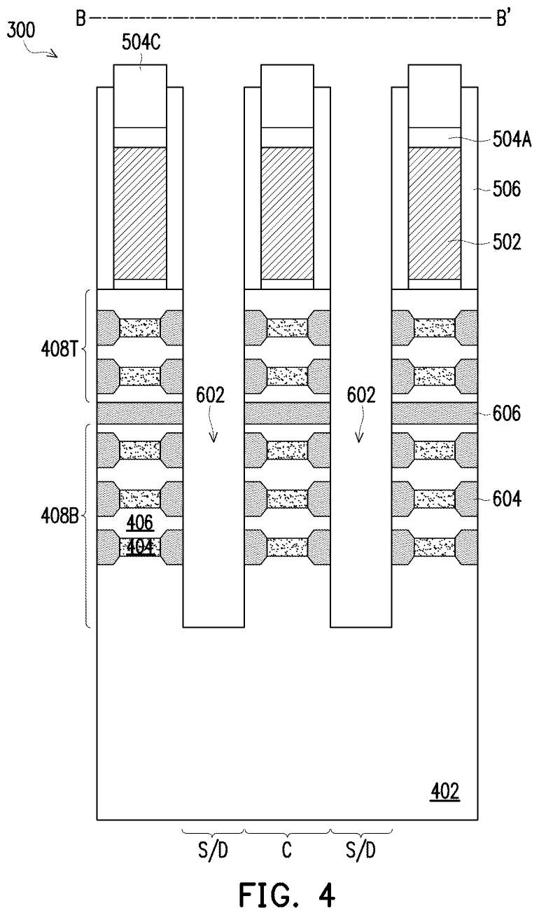

FIG. 4 illustrates respective cross-sectional views along the cut line B-B′ of the top view of FIG. 3. In an embodiment, the active regions 302 may be formed by epitaxially growing an epitaxial stack of first semiconductor layers (e.g., Si) 406 and second semiconductor layers (e.g., SiGe) 404 alternatively disposed one on another over a substrate 402. The semiconductor layers 406 are nanostructures that provide a channel region of a transistor device; the semiconductor layers 404 are sacrificial layers that are removed to form a gap within which a gate structure of the device is subsequently formed.

The substrate 402 is similar to the substrate described above in conjunction with the method 100 of FIG. 1. Substrate 402 includes an elementary semiconductor, such as silicon and/or germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP. GaInAsP, or a combination thereof; or a combination thereof. In the depicted embodiment, substrate 402 is a silicon substrate. In some embodiments, substrate 402 is a semiconductor-on-insulator substrate, such as a silicon-on-insulator (SOI) substrate, a silicon germanium-on-insulator (SGOI) substrate, or a germanium-on-insulator (GOI) substrate. Substrate 402 (and mesa 402′) can include various doped regions, such as p-type doped regions (e.g., p-wells), n-type doped regions (e.g., n-wells), or a combination thereof. N-type doped regions include n-type dopants, such as phosphorus, arsenic, other n-type dopant, or a combination thereof. P-type doped regions include p-type dopants, such as boron, indium, other p-type dopant, or a combination thereof. In some embodiments, the doped regions include a combination of p-type dopants and n-type dopants.

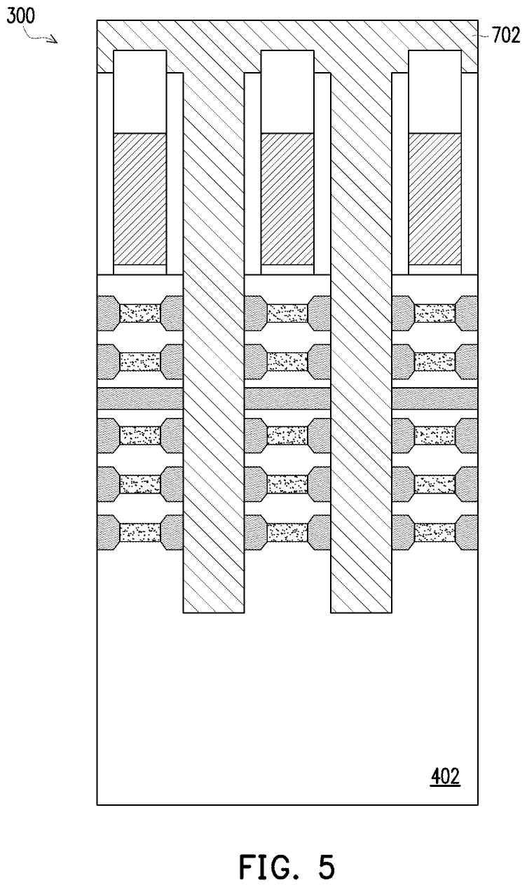

Semiconductor layers 406 and semiconductor layers 404 are epitaxially grown on the substrate 402. A composition of semiconductor layers 406 is different than a composition of semiconductor layers 404 to achieve etching selectivity and/or different oxidation rates during subsequent processing. Semiconductor layers 404 and semiconductor layers 406 include different materials, constituent atomic percentages, constituent weight percentages, thicknesses, or a combination thereof to achieve desired etching selectivity during an etching process, such as an etch process implemented to form suspended channel layers in channel region (discussed below). For example, semiconductor layers 404 include silicon germanium, semiconductor layers 406 include silicon, and a silicon etch rate of semiconductor layers 406 is different than a silicon germanium etch rate of semiconductor layers 404 to a given etchant. The present disclosure contemplates semiconductor layers 404 and semiconductor layers 406 including any combination of semiconductor materials that provides desired etching selectivity, desired oxidation rate differences, desired performance characteristics (e.g., materials that increase current flow), or a combination thereof, including any of the semiconductor materials disclosed herein. Within the stack of semiconductor layers 404, 406, is provided a layer suitable for forming the insulating layer 606 discussed below. The layer may include a same material as semiconductor layers 404 but with a varied atomic percentage that provides for increased oxidation rate. In some embodiments, the layer is silicon germanium with an increased germanium percentage. The layer is subsequently modified to provide an isolation layer (as discussed below with respect to 606) between the upper transistor and the lower transistor. FIG. 5 shows multiple channel layers 406 for a lower transistor region 408B and multiple channel layers 406 for an upper transistor region 408T. The number of channel layers 406 for each of the lower and upper transistors is not limited to that illustrated. Rather, any number of layers may be provided depending on the desired device performance for the respective transistors.

After being grown across the substrate 403, the stack of semiconductor layers 404, 406 are then patterned to define active regions 302. In some implementations, an upper region of the substrate 402 is also patterned forming mesa. The active regions 302 may be patterned by any suitable method for example by one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active regions 302 by etching the epitaxial semiconductor layers 404, 406. The etching process can include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant.

Again, in the illustrated embodiment, a bottom portion of the stack of semiconductor layers 408B includes the channel members 406 that will form a bottom transistor of the C-FET device 300 and a top portion of the stack of semiconductor layers 408T includes the channel members 406 that will form a top transistor of the C-FET device 300.

As illustrated in FIG. 3, isolation features 304 electrically isolate active device regions 302 and/or passive device regions of a device from one another. Isolation feature 304 includes silicon oxide, silicon nitride, silicon oxynitride, other suitable isolation material (including, for example, silicon, oxygen, nitrogen, carbon, other suitable isolation constituent, etc.), or a combination thereof. Isolation feature 304 may have a multilayer structure. For example, isolation feature 304 includes a bulk dielectric (e.g., an oxide layer) over a dielectric liner (including, for example, silicon nitride, silicon oxide, silicon oxynitride, silicon oxycarbonitride, or a combination thereof). In another example, isolation feature 304 includes a dielectric layer over a doped liner, such as a boron silicate glass (BSG) liner and/or a phosphosilicate glass (PSG) liner. Dimensions and/or characteristics of isolation feature 304 are configured to provide a shallow trench isolation (STI) structure, a deep trench isolation (DTI) structure, a local oxidation of silicon (LOCOS) structure, other suitable isolation structure, or a combination thereof. In an embodiment, isolation feature 304 may provide an STI.

The method 200 includes block 204 where a dummy gate structure is formed over the active regions and extending over the isolation regions. The dummy gate structures may be substantially similar to as illustrated in FIG. 5 and the gate structures 306 extending in an y-direction in FIG. 3.

Referring to the example of FIG. 5, gate structures 306 are formed that include a dummy gate 502. The dummy gate 502 may include a dummy gate electrode and a dummy gate dielectric layer. The dummy gate electrode includes a dummy gate electrode and the dummy gate dielectric. Exemplary dummy gate materials include a dummy gate electrode of polysilicon or amorphous silicon and a dummy gate dielectric of silicon oxide. The gate structures 502 are formed over a channel region C and define adjacent source/drain regions S/D in the active regions 302.

A plurality of hard mask layers denoted in FIG. 5 as 504A and 504C are provided over the gate structure 502 for protection and patterning purposes. In an embodiment, the hard mask layer 504A is a first dielectric material such as SiN, SiCN, SiOCN, or other suitable materials. In an embodiment, the hard mask layer 504C includes a second dielectric material such as SiN, SiCN, SiOCN, or other suitable materials. In some implementations, the hard mask layer 504A and hard mask layer 504C are different materials. In an embodiment, the hard mask layer 504C may also include an oxide composition. The layer 504C may include one layer (e.g., a single material), a bilayer, a multilayer, and/or other configurations including those that provide for suitable etch selectivity.

Gate spacers 506 are formed adjacent to and along sidewalls of dummy gate 502. Gate spacers 506 can include seal spacers, offset spacers, sacrificial spacers, dummy spacers, main spacers, other suitable spacers, or a combination thereof. Gate spacers 506 can have single layer structures or multilayer structures. Gate spacers 506 include a dielectric material, which can include silicon, oxygen, carbon, nitrogen, other suitable constituent, or a combination thereof (e.g., silicon oxide, silicon nitride, silicon oxynitride, silicon carbide, silicon carbonitride, silicon oxycarbide, silicon oxycarbonitride, etc.).

The method 200 includes block 206 where the source/drain regions of the device are etched to form recesses or openings. The etching process can include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Referring to the example of FIG. 4, recesses or openings 602 are etched in the S/D regions of the active regions 302. The etching of the openings 602 is selective such that it removes the semiconductor layers 406, 408 relative to the spacers 506 and hard mask layers 504.

The method 200 includes block 208 where isolation features are formed. The isolation regions of block 208 may include forming inner spacers providing isolation between a gate structure (subsequently formed) and a source/drain feature of the device. The isolation regions of block 208 may also provide an isolation layer between the set of channel regions 408B of a bottom transistor and the set of channel regions 408T of a top transistor in forming the device 300 as a C-FET device. Referring to the example of FIG. 4, after forming the openings 602, inner spacers 604 are formed on the now-exposed edges of the semiconductor layers 404. In some embodiments, forming inner spacers 604 include laterally etching semiconductor layers 404 to form gaps between semiconductor layers 406, and filling the gaps with dielectric material. In other implementations, an oxidation process is performed that transforms an edge region of the semiconductor layers 404 to dielectric material forming inner spacers 604. An insulation layer 606 is formed. In some implementations, the insulating layer 606 is formed through oxidation. In some implementations, the etch rate of a semiconductor layer is such that it can be selectively removed forming a gap, which is then filled with dielectric materials. In some implementations, the inner spacers 604 and/or the insulating layer 606 are SiGeOx, silicon oxide, or other suitable dielectrics.

The method 200 then proceeds to block 210 where dummy material is deposited in the source/drain openings to form a dummy material layer. In some implementations, the depositing of the dummy material and/or forming of the dummy material layer may be substantially similar to as discussed above with reference to block 106 of the method 100 of FIG. 1. For example, in some implementations, the dummy material is deposited by spin-on deposition. Exemplary materials used for the deposition include those provided in Table 1 above. In some embodiments, the dummy material layer formed comprises a carbon-based material, SiOC based material, SiOx based material, and/or combinations thereof. Referring to the example of FIG. 5, dummy material layer 702 is formed. In an embodiment, the dummy material layer 702 is SiOx or SiOC. The dummy material 702 is formed such that it fills the opening 602.

The method 200 then proceeds to block 212 where the dummy material layer is etched back such that it is reduced in thickness. In some implementations, the etching the dummy material layer may be substantially similar to as discussed above with reference to block 108 of the method 100 of FIG. 1. In some implementations, block 212 includes a multi-step process for example providing planarization steps, wet etching steps, and/or dry etching steps.

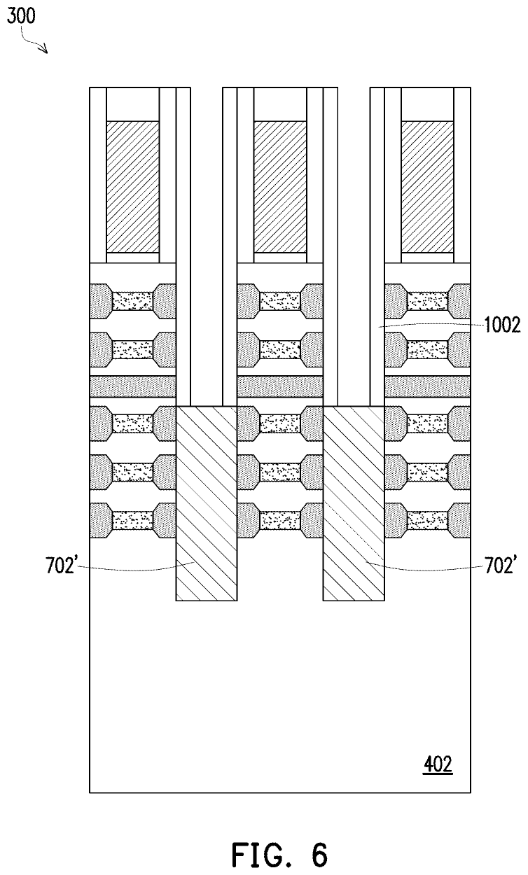

The etching back of the dummy material layer 702 reduces a thickness of the dummy material layer to form dummy material layer 702′ as shown in FIG. 6. The etching back of the dummy material layer 702′ provides an opening extending in source/drain region of the upper transistor region of the device 300. That is, the channel layers 406 of the upper transistor are adjacent the opening. In particular, the channel layers 406 of the upper transistor are laterally adjacent, or adjacent in an x-direction to the opening. In an embodiment, sidewalls of the channel layers 406 of the upper transistor are exposed in the opening. The etched back dummy material 702′ remains laterally adjacent the channel members 406 of the lower device region of the device 300. In an embodiment, the etched back dummy material 702′ is disposed directly on sidewalls of the channel layers 406 of the lower transistor.

In an embodiment, the etching back of the dummy material layer 702 to form the dummy material layer 702′ may include a plasma etching process. In an implementation, the etching process is performed at a temperature of between approximately −10° C. and approximately 250° C. In an implementation, the reactant gas of the etching process includes HF, NH₃, Ar, N₂, and/or other suitable gases. In an embodiment, the etching is performed at approximately 100 mTorr to approximately 3500 mTorr.

The method 200 includes block 214 where a dielectric liner is formed. The dielectric liner may be disposed on the etched back dummy material layer. In an embodiment, the dielectric liner is disposed on the sidewalls of the opening in the source/drain region in an upper transistor region such that the dielectric liner covers the semiconductor layers 406 of the upper transistor region. Referring to the example of FIG. 6, a dielectric liner 1002 is formed on the sidewalls of the opening. The dielectric liner 1002 is disposed on sidewalls of the semiconductor layers 406, which form channel regions of the top transistor (300T) of the device 300 as discussed in the following steps. The dielectric liner 1002 may include SiN, SiCN, SiOCN, and/or other suitable materials. The dielectric liner 1002 may be formed by atomic layer deposition (ALD), chemical vapor depositions (CVD), and/or other suitable deposition methods. In some implementations, after deposition, the dielectric liner 1002 is etched to remove deposited materials from horizontally arranged surfaces (e.g., hard mask 504B and center of the surface of etched back dummy material layer 702′).

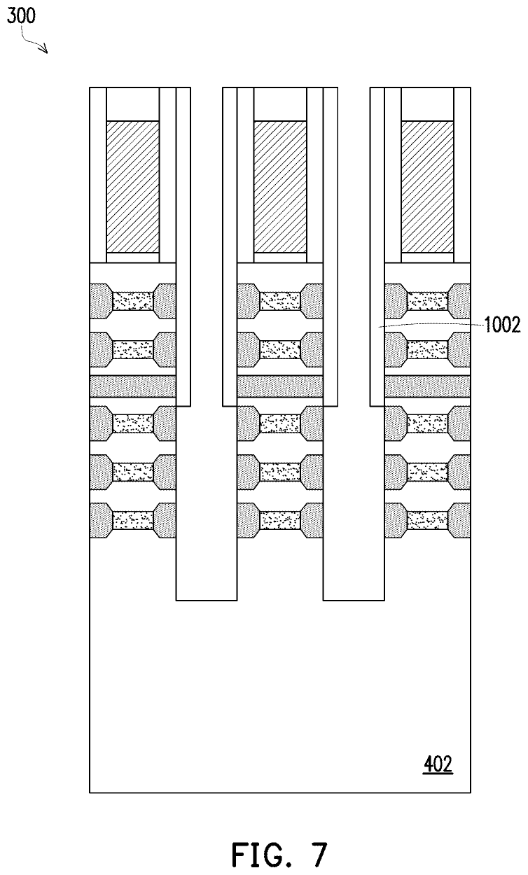

After the forming the dielectric liner 1002, the dummy material layer 702′ is removed from the substrate 402 as shown in FIG. 7. In an embodiment, the removal of the dummy material layer 702′ may be performed by plasma etching. In an implementation, the etching process is performed at a temperature of between approximately −10° C. and approximately 250° C. In an implementation, the reactant gas of the etching process includes HF, NH₃, Ar, N₂, and/or other suitable gases. In an embodiment, the etching is performed at approximately 100 mTorr to approximately 3500 mTorr.

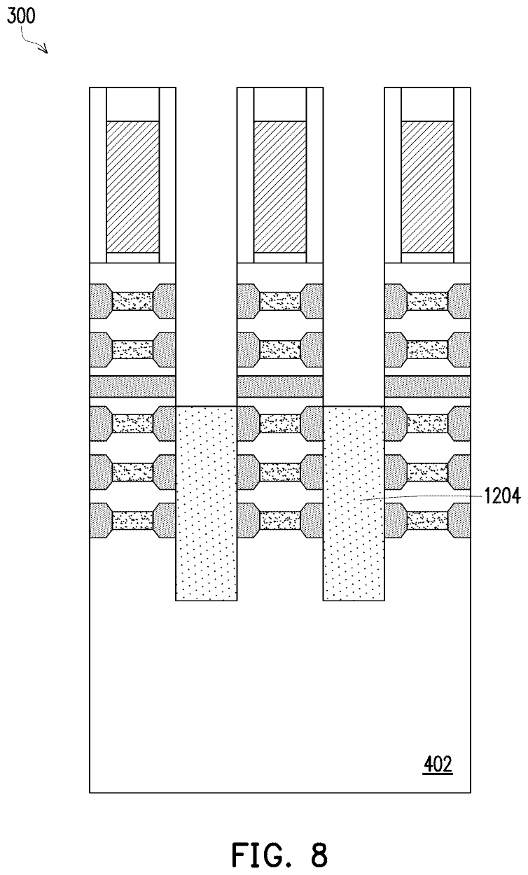

The method 200 also includes block 216 where an epitaxial layer forming a source/drain region of a bottom transistor of a C-FET is formed. The source/drain feature may be deposited using vapor-phase epitaxy (VPE), ultra-high vacuum CVD (UHV-CVD), molecular beam epitaxy (MBE), and/or other suitable processes. When the source/drain features is n-type, it may include silicon (Si) doped with an n-type dopant, such as phosphorus (P) or arsenic (As). When the source/drain features is p-type, it may include silicon germanium (SiGe) doped with a p-type dopant, such as boron (B) or boron difluoride (BF₂). In an embodiment, the source/drain features may include multiple layers. Referring to the example of FIG. 8, a source/drain epitaxial feature 1204 is provided. The source/drain epitaxial feature 1204 is associated with the lower transistor of the device 300. The source/drain epitaxial feature 1204 is grown from a seed area of the substrate 402 and the exposed sidewalls of the channel regions 406 of the lower transistor. While the epitaxial material of the source/drain features 1204 is grown, the channel regions 406 of the upper transistor region are covered by the dielectric liner 1002 thereby prohibiting epitaxial growth.

As illustrated in the example of FIG. 8, after growing the epitaxial material for the source/drain of the bottom transistor, the dielectric liner 1002 may be removed by suitable etching processes. The etching processes may include suitable wet or dry etching selective to the dielectric liner 2002.

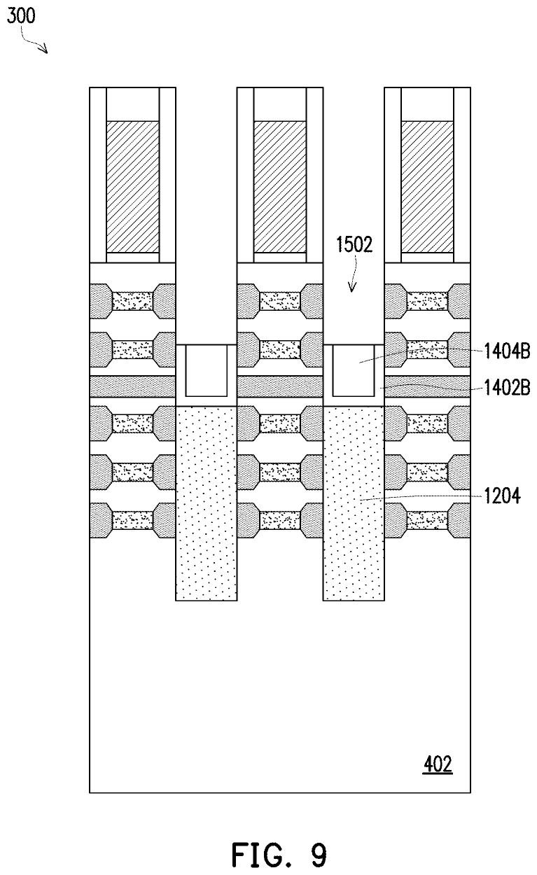

The method 200 includes a block 218 where another isolation layer(s) is formed. The isolation layer of block 218 may provide isolation between the source/drain region of a lower transistor of the C-FET and the source/drain region of an upper transistor of the C-FET. The isolation layer may include a multi-layer structure such as an interlayer dielectric (ILD) and contact etch stop layer (CESL). Referring to the example of FIG. 9, ILD 1404B and CESL 1402B are formed over the substrate 402. In an embodiment, the CESL 1402B may include silicon nitride and the ILD 1404B may include silicon oxide. Other example compositions of the CESL 1402B include silicon carbonitride, or silicon oxycarbonitride. Other example compositions of the ILD 1404B include, for example, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), Black Diamond® (Applied Materials of Santa Clara, California), xerogel, aerogel, amorphous fluorinated carbon, parylene, benzocyclobutene-based (BCB) dielectric material, SiLK (Dow Chemical, Midland, Michigan), polyimide, other suitable dielectric material, or a combination thereof. The ILD 1404B and/or CESL 1402B may be deposited using PECVD, FCVD, spin-on coating, or a suitable deposition technique. After deposition of the material for ILD 1404B and CESL 1402B, the materials are etched back to provide an opening 1502 in the source/drain region of the upper transistor of the device 300.

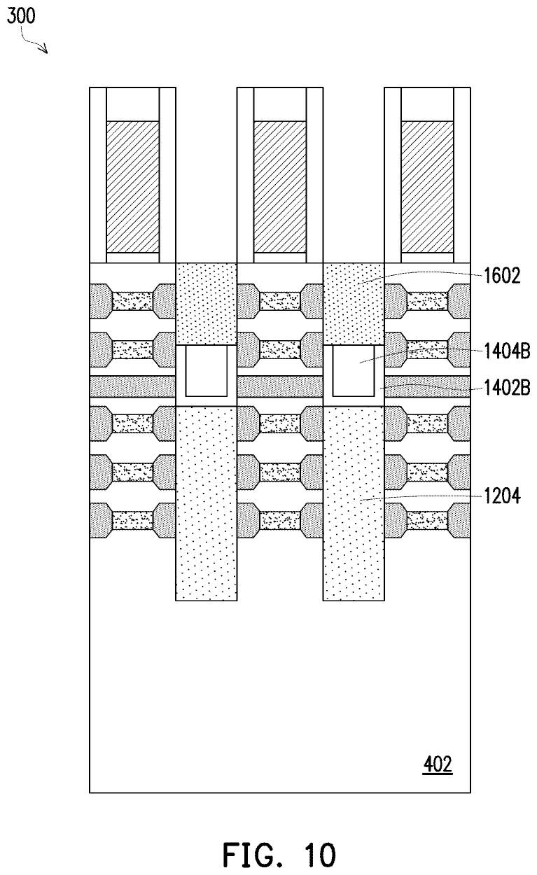

The method 200 includes a block 220 where an epitaxial layer forming a source/drain region of a top transistor of a C-FET is formed. The source/drain feature may be deposited using vapor-phase epitaxy (VPE), ultra-high vacuum CVD (UHV-CVD), molecular beam epitaxy (MBE), and/or other suitable processes. When the source/drain features is n-type, it may include silicon (Si) doped with an n-type dopant, such as phosphorus (P) or arsenic (As). When the source/drain features is p-type, it may include silicon germanium (SiGe) doped with a p-type dopant, such as boron (B) or boron difluoride (BF₂). In an embodiment, the source/drain features may include multiple layers. The source/drain feature of the upper transistor may include a different dopant type than the source/drain feature of the lower transistor (e.g., n-type and p-type). Referring to the example of FIG. 10, the source/drain epitaxial feature 1602 is formed. The source/drain epitaxial feature 1602 provides the source/drain for the upper transistor of device 300. The source/drain epitaxial feature 1602 may include a first dopant type and the source/drain epitaxial feature 1204 may include a second dopant type. In some implementations, the first dopant type is a p-type dopant and the second dopant type is an n-type dopant.

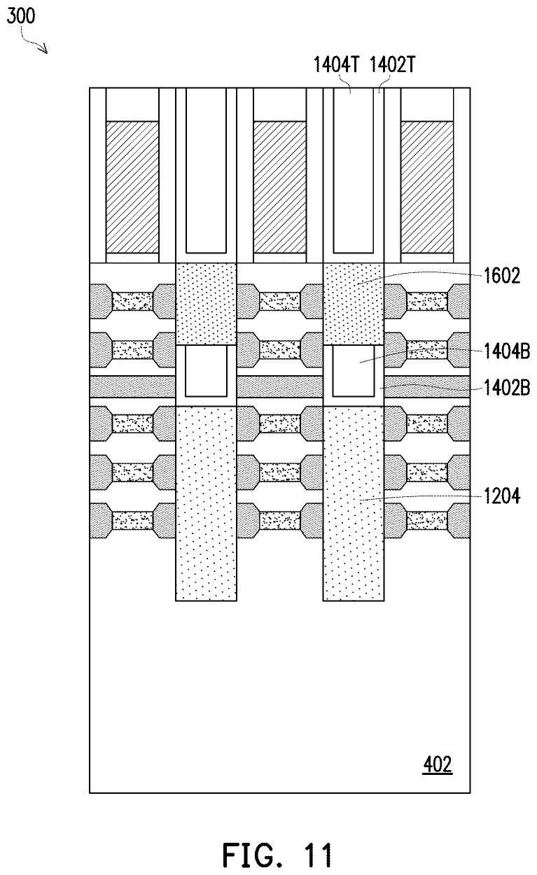

The method 200 includes a block 222 where another isolation layer(s) is formed. The isolation layers may include another interlayer dielectric (ILD) and another contact etch stop layer (CESL). The isolation layers may be substantially similar to as discussed above with reference to block 218. Referring to the example of FIG. 11. ILD 1404T and CESL 1402T are formed over the substrate 402. In an embodiment, the CESL 1402T may include silicon nitride and the ILD 1404T may include silicon oxide. Other example compositions of the CESL 1402T include silicon carbonitride or silicon oxycarbonitride. Other example compositions of ILD 1404T include, for example, silicon oxide, carbon doped silicon oxide, silicon nitride, silicon oxynitride, tetraethyl orthosilicate (TEOS)-formed oxide, boron silicate glass (BSG), phosphosilicate glass (PSG), borophosphosilicate glass (BPSG), fluorosilicate glass (FSG), Black Diamond® (Applied Materials of Santa Clara, California), xerogel, aerogel, amorphous fluorinated carbon, parylene, benzocyclobutene-based (BCB) dielectric material, SILK (Dow Chemical, Midland, Michigan), polyimide, other suitable dielectric material, or a combination thereof. A planarization process may be performed after the deposition by PECVD, FCVD, spin-on coating, or a suitable deposition technique. The ILD 1404 and CESL 1402 provided in block 218 may be the same of different compositions than those provided in block 222.

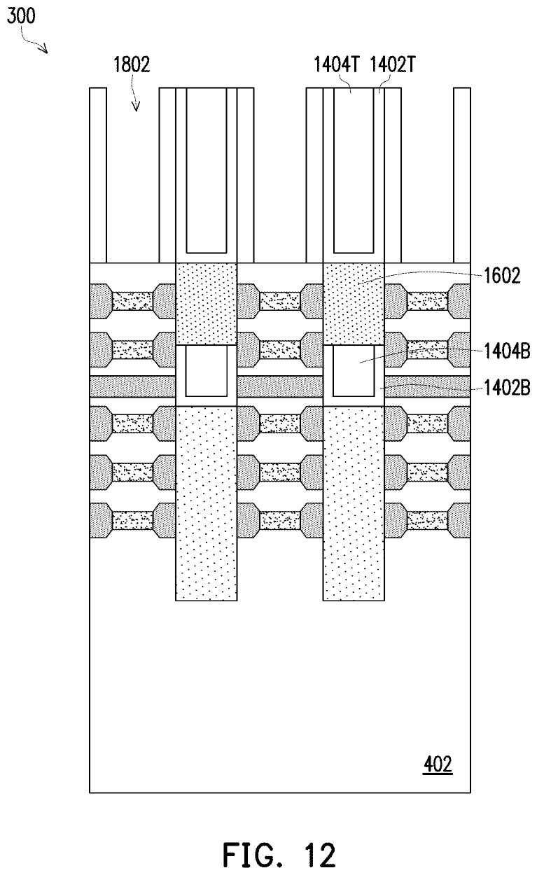

The method 200 includes block 224 where replacement gate is formed. The replacement gate is formed by a process that includes removing the dummy gate, releasing the channel layers, and forming a metal gate having an upper portion associated with an upper transistor and a lower portion associated with a lower transistor. Referring to the example of FIG. 12, dummy gate 502 is removed to form a gate opening 1802 that exposes an upper channel layer 406. Gate opening 1802 has sidewalls formed by gate spacers 506. After removal of the dummy gate, as illustrated in FIG. 13, the semiconductor layers 406, forming the channel layers of the device, are released. The channel release process may include selectively removing semiconductor layers 404 to form gaps 1902 between semiconductor layers 406 and between semiconductor layers 406 and substrate 402, thereby suspending semiconductor layers 406 in channel region of the device 300. The suspended semiconductor layers 406 are provided in two sets-one set for the lower transistor channel regions and one set for the upper transistor channel regions. In the illustrated embodiment, two suspended semiconductor layers 406 are vertically stacked along the z-direction and provide two channels through which current can flow between epitaxial source/drain features 1204 for a bottom transistor and two suspended semiconductor layer 406 are vertically stacked along the z-direction and provide two channels through which current can flow between source/drain features 1602 for a top transistor. However, in other implementations, any number of suspended semiconductor layers may be provided. Suspended semiconductor layers 406 are referred to hereafter as channel layers or members or channel nanostructures.

After the channel release, gate structures are formed for the device. The gate structures may be metal gate structures and include a lower portion or lower gate stack and an upper portion or upper gate stack for the lower and upper transistor of the device respectively. The gate stacks include gate electrode layers and gate dielectric layers. In an embodiment, the gate electrode of the bottom transistor provides a first work function and the gate electrode of the top transistor provides a second work function.

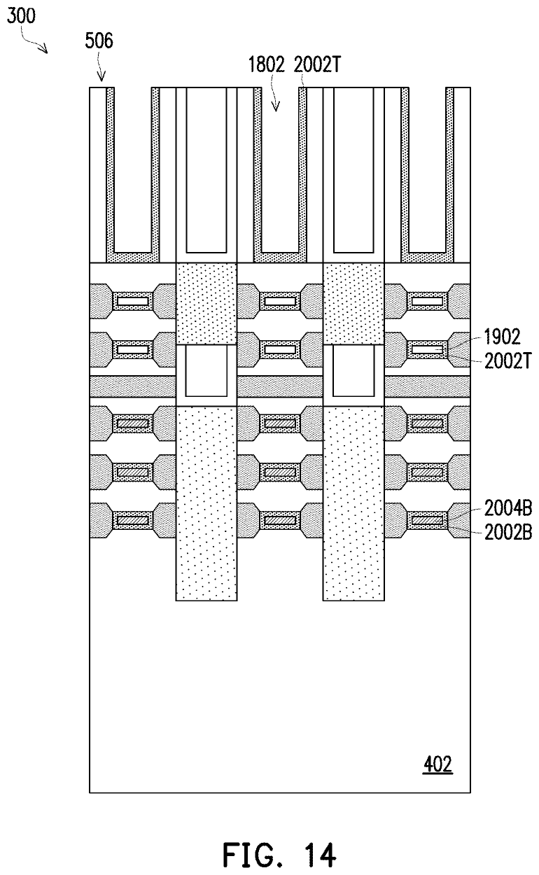

As illustrated in example of FIG. 14, a gate dielectric layer 2002 is formed on the channel regions 406. The gate dielectric layer 2002 for the bottom device 300B is noted as 2002B and the gate dielectric layer 2002 for the top device 300A is noted as 2002T. In some implementations, the gate dielectric layers 2002T, 2002B include a same material. The gate dielectric layer 2002 may include an interfacial layer and/or a high-k dielectric layer. A high-k dielectric material generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or a combination thereof.

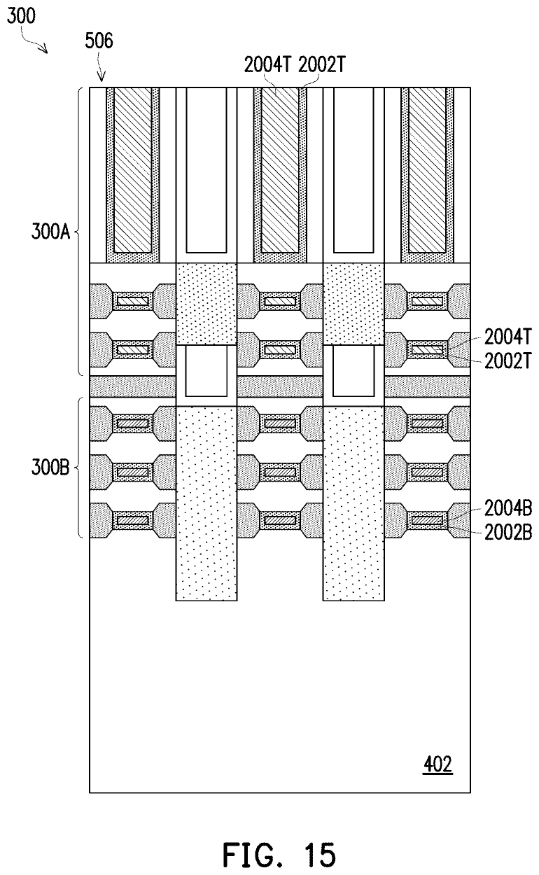

A first gate electrode layer 2004B is formed in the bottom transistor 300B. As illustrated in FIG. 15, a second gate electrode layer 2004T is formed in the top transistor 300T. In one embodiment, the first work function layer 2004B is a p-type work function layer and the second work function layer 2004T is an n-type work function layer. In another example, the first work function layer 2004B is an n-type work function layer and the second work function layer 2004T is a p-type work function layer. Example n-type work function materials include Ti, Al, Ag, Mn, Zr, TiAl, TiAlC, TaC, TaCN, TaSiN, TaAl, TaAlC, or TiAlN. Example p-type work function materials include TiN, TaN, Ru, Mo, Al, WN, ZrSi₂, MoSi₂, TaSi₂, NiSi₂, or WN. The gate electrode layer 2004 and gate dielectric layer 2002 together form the gate structure 306, see FIG. 3.

The method 200 may continue to block 226 where additional processing is performed. In some embodiments, various interconnects of multi-layer interconnect (MLI) features are formed to facilitate operation of C-FET device 300. MLI feature electrically couples various devices (for example, transistors, resistors, capacitors, and/or inductors) and/or components (for example, gate structures and/or source/drain features) of device 300, such that the various devices and/or components can operate as specified by design requirements of the C-FET device. MLI feature includes a combination of dielectric layers, such as ILD layers and conductive layers configured to form various interconnects. During operation of the C-FET device 300, the interconnects are configured to route signals between the devices and/or the components of C-FET 300, including to the lower transistor 300B and the upper transistor 300A, and/or distribute signals (for example, clock signals, voltage signals, and/or ground signals) to the devices and/or the components of device 300. The conductive layers are configured to form vertical interconnects, such as device-level contacts and/or vias, and/or horizontal interconnects, such as conductive lines. Vertical interconnects typically connect horizontal interconnects in different layers (or different planes) of MLI feature.

Thus, the C-FET device 300 includes a first, lower transistor 300B and a second, upper transistor 300A. In other embodiments, transistors of a stacked transistor structure, such as stacked transistors 300A and 300B of the device 300, can be fabricated separately, monolithically, or sequentially. When fabricated separately, a top transistor and a bottom transistor may be separately fabricated, and then, the top transistor is bonded/attached to the bottom transistor. When fabricated sequentially, a first set of semiconductor layers may be processed to form a bottom transistor, and then, a second set of semiconductor layers is attached/bonded to the bottom transistor and processed to form a top transistor (i.e., the top transistor is fabricated on the bottom transistor). In the fabrication methods, one or more dummy material layers may be formed according to aspects of the method 100 and 200 where the dummy material layer(s) are used to mask certain portions of the device while processing other portions of the device.

In another exemplary embodiment of the method 100 of FIG. 1, a method 2200 of FIG. 16 provides an implementation of the method 100. In particular, as discussed below, in an exemplary device in block 104 of the method 100, a C-FET device at an interim point in fabrication having an opening for receiving dummy material layer is provided. As illustrated below, the method 2200 provides the opening in the channel region of the device by the removal of a dummy gate structure and within this opening a dummy material layer is formed such as described in block 106 of the method 100.

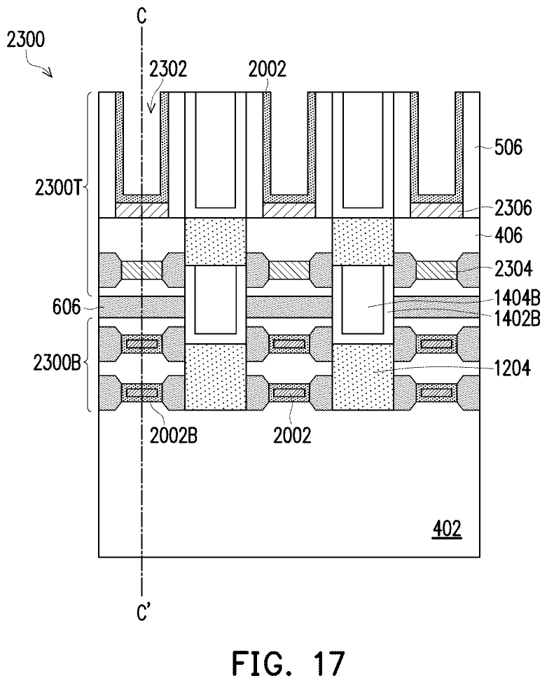

FIG. 16 is a flow chart of a method 2200 for fabricating a C-FET device, according to aspects of the present disclosure. Additional steps can be provided before, during, and after the method 2200, and some of the steps can be provided before, during, and after the method 2200. FIGS. 17-24 illustrate cross-sectional views of a device 2300 providing exemplary illustrations of steps of the method 2200. FIG. 3 also illustrates a top, diagrammatic view of a C-FET device that correspond to the C-FET device 2300. FIGS. 17-24 are fragmentary and are simplified for ease of description and understanding. Additional features can be added to the C-FET device 2300 of FIGS. 17-24, and some of the features below can be replaced, modified, or eliminated in other embodiments.

The method 2200 includes block 2202 were an interim structure of a C-FET device is provided. The interim structure provided in block 2202 may be within a gate loop process (e.g., formation of the gate structure) during the fabrication of a C-FET device. In an embodiment, features of a bottom transistor of a C-FET have been formed (e.g., gate and source/drain terminals). And with respect to a top transistor of the C-FET, source/drain features have been formed, and a steps to form the gate structure of the top transistor are to be conducted.

Referring to the example of FIG. 17, a device 2300 is provided. FIG. 17 illustrates an interim structure during fabrication of the C-FET device 2300, in particular provided during a gate stack formation loop. The device 2300 may be substantially similar to the device 300. In particular, in an embodiment, the interim structure of the device 2300 shares features of the structure of FIG. 15, discussed above with reference to the method 200. In other words, steps have been performed to form and release channel layers 406 in a channel region and source/drain features 1204 and 1602 are formed in a source/drain region. A gate structure including a gate electrode 2004B and a gate dielectric 2002B for a bottom transistor, denoted 2300B, of the device 2300 have been fabricated.

The method 2200 provides an example of forming the gate structure of the upper device of the C-FET device 2300. Referring to the example of FIG. 17, an opening 2302 is provided over the channel region of the device 2300. In an embodiment, the opening 2302 is provided by the removal of a dummy gate structure. The dummy gate structure removed to form the opening 2302 may be substantially similar to the dummy gate 502 and its removal to form the opening 1802, which are discussed above with reference to the method 200 and the device 300. In the interim stage of FIG. 17, the gate structure of the top device 2300A has yet to be formed. As such, the top device 2300A includes a dummy plug 2304 between channel members 406. In an embodiment, the dummy plug 2304 includes a dielectric material such as aluminum oxide. The dummy plug 2304 may protect the channel members 406 of the upper transistor 2300T during processing the gate structure of the bottom transistor 2300B. Similarly, a hard mask layer 2306 may be formed on an uppermost channel member 406.

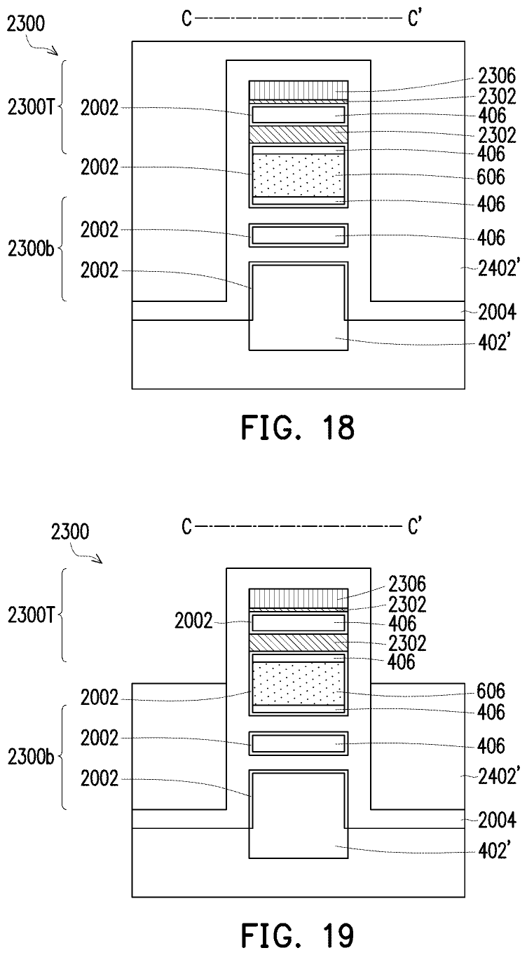

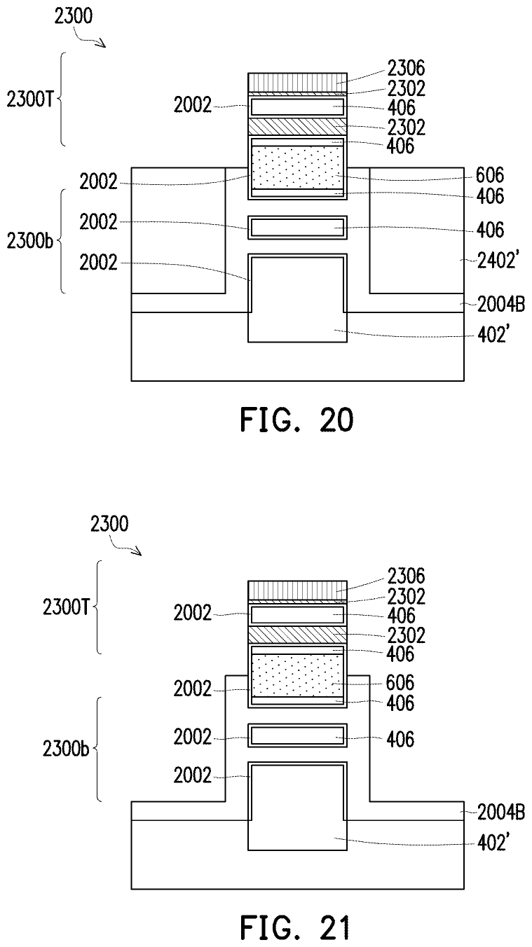

The method 2200 includes block 2204 where dummy material is deposited to form a dummy material layer in an opening of the interim device structure. Referring to the example of the device 2300, FIG. 18 provides a fragmentary, cross-sectional view along cut C-C′ of FIG. 20 where a dummy material layer 2402 has been formed in opening 2302. It is noted that the cross-sectional view of cut C-C′ is simplified to illustrate a single suspended channel layer 406 for each of the upper transistor 2300T and the lower transistor 2300B. Any number of channel layers 406 may be implemented dependent upon the design of the C-FET device 2300.

In an embodiment, the dummy material layer 2402 is formed in the opening 2302. The dummy material layer 2402 may be formed according to aspects of the method 100. That is, in some implementations, the dummy material layer 2402 is deposited in the opening 2302 according to aspects of the block 106 of the method 100 of FIG. 1. For example, in some implementations, the dummy material layer 2402 is formed by a spin-on deposition process. In an embodiment, the dummy material layer 2402 includes SiOx or SiOC. In some implementations, the dummy material layer 2402 is SiOx or SiOC formed by depositing one or more of the materials of Table 1 discussed above. Deposition methods provided by the block 106 of the method 100 may provide the dummy material layer 2402 in the opening 2302 such that the layer is formed with a uniform structure (e.g., without seams or voids).

The method 2200 includes block 2206 where the dummy material layer is etched back such that it is reduced in thickness. The etching back process may be provided by planarization processes, wet etching processes, dry etching processes, and/or other suitable methods. In some implementations, block 2206 includes a multi-step process, for example, providing planarization steps, wet etching steps, and/or dry etching steps in combination. Referring to the example of the device 2300 at FIG. 19, the dummy material layer 2402 has been etched back to form dummy material layer 2402′. In an embodiment, the dummy material layer 2402 is etched back such that it is laterally adjacent the channel regions 406 of a lower transistor, while being removed from a region adjacent the channel regions 406 of an upper transistor. In an embodiment, the etching back of the dummy material layer to form the dummy material layer 2402′ may be a plasma etching. In an implementation, the etching process is performed at a temperature of between approximately −10° C. and approximately 250° C. In an implementation, the reactant gas of the etching process includes HF, NH₃, Ar, N₂, and/or other suitable gases. In an embodiment, the etching is performed at approximately 100 mTorr to approximately 3500 mTorr.

The method 2200 includes block 2208 where gate materials of the first type are removed from the upper transistor region. Referring to the example of FIG. 20, the metal layer 2004 is removed from the area of the upper transistor leaving the metal layer 2004B adjacent the channel regions 406 of the lower transistor 2300B. In some implementations, the gate dielectric layer 2002 is maintained in both the lower transistor 2300B region and the upper transistor 2300T region.

In some implementations, the metal gate 2004B may have a work function tuned to a first device type (e.g., a p-type work function) that device type being associated with the bottom transistor 2300B. As a second device type (e.g., n-type work function) is desired for the top device 2300A, it desired to remove the metal gate material 2004. The metal gate 2004B may be removed in an etching process conducted at a temperature of between approximately 20° C. and approximately 75° C. In an embodiment, the metal gate 216P is removed by an etching process (e.g., plasma etching) that includes an etching gas of H₂O, H₂O₂, NH₄OH, and/or other suitable gases. The etching process may be a selective etching process targeting the conductive material of the metal gate 2004B.

The method 2200 then proceeds to block 2210 where after removing the metal gate from an upper transistor region, the dummy material layer is removed from the substrate. Referring to the example of FIG. 21, dummy material layer 2402′ is removed. In an embodiment, the removal of the dummy material layer 2402′ is performed using an etching process at a temperature of between approximately −10° C. and approximately 250° C. In an embodiment, the dummy material layer 2402′ is removed by an etching process implementing reactant gases (and carrier gases) of HF, NH₃, Ar, N₂, and/or other suitable gases. In an embodiment, the dummy material 2402′ is removed at process pressure of between approximately 10 mTorr and approximately 3500 mTorr.

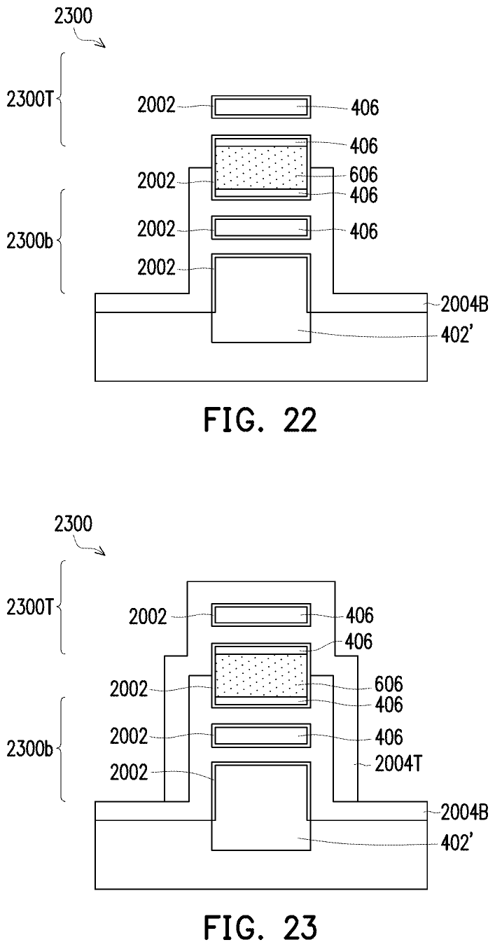

The method 2200 then proceeds to block 2212 where the dummy plug and the hard mask layer are removed to release the channel layers of the upper transistor. Referring to the example of FIG. 22, the hard mask 2306 and the dummy plug 2304 are removed from the device 2300. In an embodiment, the removal is performed by selective etching processes such as a selective wet etching process. After removing the hard mask 2306 and the dummy plug 2304, the upper channel members 406 are surrounded by a gap as illustrated in FIG. 22.

The method 2200 then proceeds to a block 2214 where a gate material of a second type is deposited. The gate material of the second type may be selected to provide a work function for the upper transistor of the device. Referring to the example of the device 2300, a metal gate electrode material, denoted 2004T as illustrated in FIG. 23, is deposited. The metal gate electrode 2004T may provide a different work function that the metal gate material previously deposited to form metal gate 2004B. In one embodiment, a first work function layer provides metal gate 2004B, which is a p-type work function layer and a second work function layer provides metal gate 2004T as an n-type work function layer. In another example, the first work function layer provides metal gate 2004B as an n-type work function layer and the second work function layer provides metal gate 2004T as a p-type work function layer. Example n-type work function materials include Ti, Al, Ag, Mn, Zr, TiAl, TiAlC, TaC, TaCN, TaSiN, TaAl, TaAlC, or TiAlN. Example p-type work function materials include TiN, TaN, Ru, Mo, Al, WN, ZrSi₂, MoSi₂, TaSi₂, NiSi₂, or WN. FIG. 26 illustrates the cross-sectional view of the channel regions along the C-C cut providing an upper channel layer 406 surrounded by the gate stack of the gate electrode 2004T and the gate dielectric 2002T and a lower channel layer 406 surrounded by the gate stack of the gate electrode 2004B and the gate dielectric 2002B.

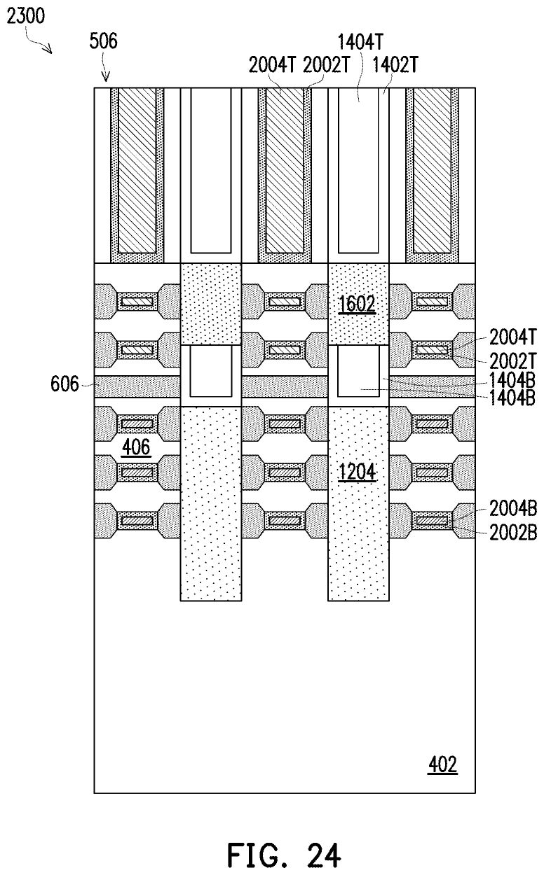

FIG. 24 illustrates a corresponding cross-sectional view along the channel (e.g., cut direction between two source/drain features) of the C-FET device 2300. The method 2200 then continues to additional fabrication. The additional fabrication may be substantially similar to as discussed above with reference to block 226 of the method 200 of FIG. 2.

As described above, the top device of a C-FET and the bottom device of a C-FET have different composition requirements to affect the different performances. For that reason, they require differentiated processing. One way to provide differentiated processing is the use of dummy material layers, such as the dummy material layer 2402 described in the embodiment of the C-FET device 2300 and the dummy material layer 702 described in the embodiment of the C-FET device 300. As described in detail above, a dummy material layer 702 and/or the dummy material layer 2402 are formed according to the method 100 of FIG. 1 to provide for a uniform composition of the dummy material layers.

In one exemplary aspect, the present disclosure is directed to a method. The method includes providing a first set of channel nanostructures and a second set of channel nanostructures stacked in a vertical direction above a semiconductor substrate. An opening is provided over the semiconductor substrate. Using spin-on deposition, a dummy material is deposited in the opening adjacent one of the first set or the second set of channel nanostructures. A process is performed while the dummy material is in the opening. After performing the process, the dummy material is removed and a first gate is formed surrounding the first set of channel nanostructures and a second gate surrounding the second set of channel nanostructures.

In an embodiment, the dummy material is one of SiOC or SiOx, where x is greater than 0. In some implementations, the depositing the dummy material includes introducing at least one compound of the Table where of the following compounds wherein R, R1, R2, R3 are each an alkyl series and each of n, l and m are greater than 0. In an embodiment, providing the opening includes etching the opening in a source/drain region. The opening may be provided by removing a dummy gate structure to provide the opening. In an embodiment, prior to performing the process, the dummy material is etched back.

In some implementations, the process includes depositing a liner layer on sidewalls of the opening. In some implementations, the process includes removing a portion of a metal gate layer adjacent the second set of channel nanostructures while the dummy material is adjacent the first set of channel nanostructures.

In another of the broader embodiments of the disclosure, a method is provided that includes receiving a substrate having a plurality of vertically stacked channel layers. A first transistor of a first type having a channel region in a first one of the plurality of vertically stacked channel layers and a second transistor of a second type having a channel region in a second one of the plurality of vertically stacked channel layers are formed. Using spin-on deposition, a dummy material is deposited laterally adjacent the first one of the plurality of vertically stacked channel layers and laterally adjacent the second one of the plurality of vertically stacked channel layers. The deposited dummy material to provide a top surface of the dummy material below the second one of the plurality of vertically stacked channel layers. A process is performed directed to the second transistor.

In an embodiment, the process of the method includes removing a metal layer adjacent the second one of the plurality of vertically stacked channel layers. And another metal layer may be formed surrounding the second one of the plurality of vertically stacked channel layers. The another metal layer has a different work function than the metal layer. In an embodiment, the process of the method includes etching depositing a dielectric liner layer on the second one of the plurality of vertically stacked channel layers. In an embodiment, the dielectric liner layer is disposed directly on the dummy material. The spin-on deposition includes depositing least one compound from a group of compounds consisting of a compound of:

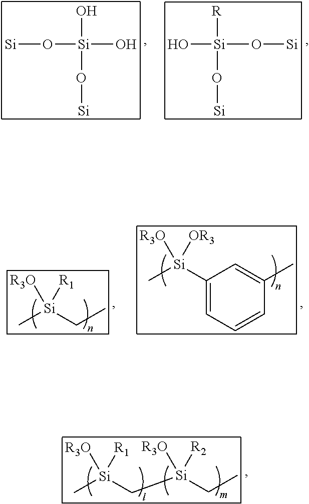

and wherein R, R1, R2, R3 are each an alkyl series and each of n, l and m are greater than 0.

In another of the broader methods discussed herein, a trench is formed in a source drain region of a transistor stack. The trench extends through a source/drain region of an upper transistor and a lower transistor. A dummy material is deposited filling the trench. And the dummy material is etched to form an opening in the trench in the source/drain region of the upper transistor and the etched back dummy material disposed in the source/drain region of the lower transistor. A dielectric liner is deposited on sidewalls of the opening in the source/drain region of the upper transistor. The etched back dummy material is removed, and a first epitaxial region associated with the lower transistor is formed while the dielectric liner is on the sidewalls of the opening in the source/drain region of the upper transistor.

In a further embodiment, the dielectric liner is removed, and an isolation layer is formed on the first epitaxial region in the trench. A second epitaxial region associated with the upper transistor is formed over the isolation layer. In a further embodiment, the method includes forming a metal gate structure for each of the lower transistor and the upper transistor. In an embodiment, the depositing the dummy material includes spin-on deposition process. And the spin-on deposition provides at least one of compound of a group of compounds consisting of:

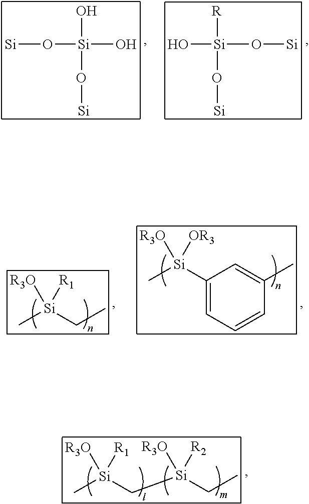

and wherein R, R1, R2, R3 are each an alkyl series and each of n, l and m are greater than 0. In some implementations of the method, the etching back the dummy material includes a planarization process followed by a plasma etching process.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a first set of channel nanostructures and a second set of channel nanostructures stacked in a vertical direction above a semiconductor substrate;
providing an opening over the semiconductor substrate;
using spin-on deposition to deposit a dummy material in the opening adjacent one of the first set or the second set of channel nanostructures;
performing a process while the dummy material is in the opening;
after performing the process, removing the dummy material; and
forming a first gate surrounding the first set of channel nanostructures and a second gate surrounding the second set of channel nanostructures.

2. The method of claim 1, wherein the dummy material is one of SiOC or SiOx.

3. The method of claim 1, wherein the depositing the dummy material includes introducing at least one compound of the following compounds: 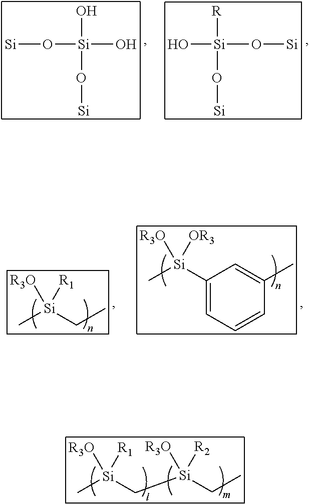
and wherein R, R1, R2, R3 are each an alkyl series and each of n, l and m are greater than 0.

4. The method of claim 1, wherein the providing the opening includes etching the opening in a source/drain region.

5. The method of claim 1, wherein the providing the opening includes removing a dummy gate structure to provide the opening.

6. The method of claim 1, further comprising:
prior to performing the process, etching back the dummy material.

7. The method of claim 1, wherein the performing the process includes depositing a liner layer on sidewalls of the opening.

8. The method of claim 1, wherein the performing the process includes removing a portion of a metal gate layer adjacent the second set of channel nanostructures while the dummy material is adjacent the first set of channel nanostructures.

9. A method, comprising:
receiving a substrate having a plurality of vertically stacked channel layers;
forming a first transistor of a first type having a channel region in a first one of the plurality of vertically stacked channel layers and forming a second transistor of a second type having a channel region in a second one of the plurality of vertically stacked channel layers;
using spin-on deposition to deposit a dummy material laterally adjacent the first one of the plurality of vertically stacked channel layers and laterally adjacent the second one of the plurality of vertically stacked channel layers; and
etching back the deposited dummy material to provide a top surface of the dummy material below the second one of the plurality of vertically stacked channel layers; and
performing a process directed to the second transistor.

10. The method of claim 9, wherein the process includes removing a metal layer adjacent the second one of the plurality of vertically stacked channel layers.

11. The method of claim 10, further comprising: forming another metal layer surrounding the second one of the plurality of vertically stacked channel layers, wherein the another metal layer has a different work function than the metal layer.

12. The method of claim 9, wherein the process includes etching depositing a dielectric liner layer on the second one of the plurality of vertically stacked channel layers.

13. The method of claim 12, wherein the dielectric liner layer is disposed directly on the dummy material.

14. The method of claim 9, wherein the spin-on deposition includes depositing least one compound from a group of compounds consisting of: 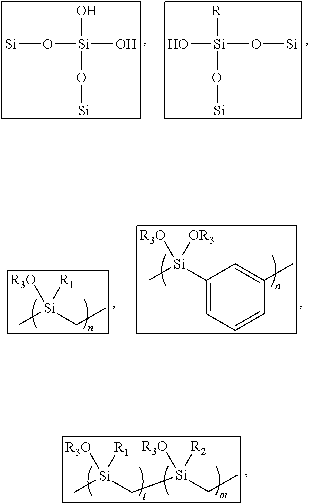
and wherein R, R1, R2, R3 are each an alkyl series and each of n, l and m are greater than 0.

15. A method, comprising:
forming a trench in a source drain region of a transistor stack, the trench extending through a source/drain region of an upper transistor and a lower transistor;
depositing a dummy material filling the trench;
etching back the dummy material to form an opening in the trench in the source/drain region of the upper transistor and the etched back dummy material disposed in the source/drain region of the lower transistor;
depositing a dielectric liner on sidewalls of the opening in the source/drain region of the upper transistor;
removing the etched back dummy material; and
forming a first epitaxial region associated with the lower transistor while the dielectric liner is on the sidewalls of the opening in the source/drain region of the upper transistor.

16. The method of claim 15, further comprising:
removing the dielectric liner;
forming an isolation layer on the first epitaxial region in the trench; and
forming a second epitaxial region associated with the upper transistor over the isolation layer.

17. The method of claim 16, further comprising:
forming a metal gate structure for each of the lower transistor and the upper transistor.

18. The method of claim 15, wherein the depositing the dummy material includes spin-on deposition process.

19. The method of claim 18, wherein the spin-on deposition process provides at least one of compound of a group of compounds consisting of: 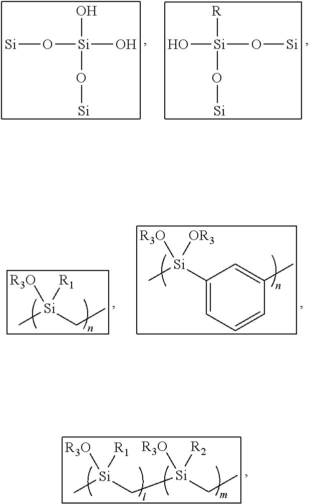
and wherein R, R1, R2, R3 are each an alkyl series and each of n, l and m are greater than 0.

20. The method of claim 15, wherein the etching back the dummy material includes a planarization process followed by a plasma etching process.
